(19) United States
(12) Patent Application Publication
(10) Pub. No.: US 2015/0303633 A1
(43) Pub. Date: Oct. 22, 2015

(54) IMPROVED SLIP RING DEVICES, SYSTEMS, AND METHODS

(71) Applicants: Russell Altieri, (US); Mark R. Jolly, (US); Warren F. Brannan, (US); Donald R. Morris, JR., (US); Michael W. Trull, (US); Richard Martin, (US); LORD Corporation, Cary, NC (US)

(72) Inventors: Russell E. Altieri, Holly Springs, NC (US); Mark R. Jolly, Raleigh, NC (US); Warren F. Brannan, Sanford, NC (US); Donald R. Morris, JR., Wendell, NC (US); Michael W. Trull, Apex, NC (US); Richard Martin, Delaplane, VA (US)

(21) Appl. No.: 14/441,003

(22) PCT Filed: Nov. 8, 2013
(86) PCT No.: PCT/US2013/069167

§ 371 Date: May 6, 2015

Related U.S. Application Data
(60) Provisional application No. 61/724,593, filed on Nov. 9, 2012.

(51) Int. Cl. H01R 39/08; H02J 5/00; H04B 5/00; G01R 31/04; G01R 31/327

(52) U.S. Cl. CPC H01R 39/08; G01R 31/04; G01R 31/327; H04B 5/0037; H02J 5/005

(57) ABSTRACT

Improvements to slip rings (200) and methods for the operation thereof include an improved slip ring assembly (200) that has a stationary element (202), a rotating element (210) rotatable with respect to the stationary (202) element, a bearing assembly coupled between the stationary element (202) and the rotating element (210), and one or more contact brushes (213) on one of the stationary element (202) or the rotating element (210). In some embodiments, the bearing assembly includes a primary bearing, a secondary bearing, a shear pin coupling the secondary bearing to the primary bearing, and an electrical monitoring circuit (206) in communication with the shear pin. In some embodiments, the one or more contact brushes (213) includes one or more metal fiber brushes constructed of a plurality of metal fibers that are configured to transmit one or more of electrical power or data between the stationary element (202) and the rotating element (210).

### PRIORITY CLAIM

The present application claims the benefit of and priority to U.S. Provisional Patent Application Ser. No. 61/724,593, filed Nov. 9, 2012, the disclosure of which is incorporated herein by reference in its entirety.

### TECHNICAL FIELD

The subject matter disclosed herein relates generally to improvements to slip rings and deicing thereof.

### BACKGROUND

Most helicopter types use electric resistance heating systems for preventing ice build-up on their rotors. These de-icing systems traditionally use a slip ring that incorporates monolithic brush systems to transmit the electrical power needed by the heating elements across the rotating interface between the stationary engine or gearbox and the rotating rotor. Although this arrangement can be considered generally sufficient for providing power to de-icing systems, future rotor systems will likely contain more electromechanical functionality, which will place additional demands on slip ring reliability and performance. Examples include rotorhead based active vibration control (AVC) and active rotors systems, both of which may have severe failure modes.

Besides being difficult to maintain, current slip ring technology has further proven to be universally unreliable and maintenance intensive. For example, current slip ring technology does not operate well in the cold, dry air encountered at typical operating altitudes. Another problem is that current slip ring technology is subject to deterioration and cracking resulting from minuscule amounts of oil often found leaking from rotor actuation systems. There is often wear on the mating slip ring, and a by-product of such wear is the creation of flammable, conductive carbon dust as the slip rings wear.

In view of these issues, it would be desirable for a slip ring design to provide increased service life, improved reliability, greater resistance to contaminants, less wear debris, increased power capability, higher and cleaner data rates, higher durability, and/or reduced maintenance demands, with such improvements leading to increased aircraft availability relative to conventional slip ring designs.

### SUMMARY

In accordance with the disclosure provided herein, improvements to slip rings and deicing thereof are provided.

In many aspects, the subject matter disclosed herein provides for an improved slip ring assembly and method. In one aspect, the improved slip ring assembly includes a stationary element, a rotating element rotatable with respect to the stationary element, and one or more metal fiber brushes on one of the stationary element or the rotating element. Each of the one or more metal fiber brushes includes a plurality of metal fibers, and the one or more metal fiber brushes transmit one or more of electrical power or data between the stationary element and the rotating element.

In further aspects, an improved slip ring assembly includes a stationary element, a rotating element rotatable with respect to the stationary element, a bearing assembly coupled between the stationary element and the rotating element, and one or more contact brushes on one of the stationary element or the rotating element, the one or more contact brushes being configured to transmit one or more of electrical power or data between the stationary element and the rotating element. The bearing assembly includes a primary bearing, a secondary bearing, a shear pin coupling the secondary bearing to the primary bearing, and an electrical monitoring circuit in communication with the shear pin.

In further aspects, a method for transmitting one or more of electrical power or data between a stationary element and a rotating element includes coupling a bearing assembly between a stationary element and a rotating element rotatable with respect to the stationary element, where the bearing assembly includes a primary bearing, a secondary bearing, and a shear pin coupling the secondary bearing to the primary bearing. The method further includes measuring a resistance of the shear pin, comparing the resistance of the shear pin to a predetermined resistance corresponding to an intact state of the shear pin, and indicating that the shear pin has broken if the resistance of the shear pin differs from the predetermined resistance.

These and other objects of the present disclosure as can become apparent from the disclosure herein are achieved, at least in whole or in part, by the subject matter disclosed herein.

### BRIEF DESCRIPTION OF THE DRAWINGS

FIG. 1A illustrates a partial side view of a monolithic carbon or metal-graphite brush contacting a slip ring.

FIG. 1B illustrates a partial side view of a metal brush contacting a slip ring.

FIG. 2A illustrates a partial side view of a metal fiber brush contacting a slip ring according to an embodiment of the subject matter disclosed herein.

FIG. 2B illustrates an arrangement of metal fibers of a metal fiber brush according to an embodiment of the subject matter disclosed herein.

FIGS. 3A and 3B illustrate a main rotor slip ring assembly according to an embodiment of the subject matter disclosed herein.

FIG. 4 illustrates a main rotor standpipe assembly according to an embodiment of the subject matter disclosed herein.

FIG. 5 illustrates a block diagram of a main rotor slip ring assembly according to an embodiment of the subject matter disclosed herein.

FIG. 6 illustrates a tail rotor slip ring assembly according to an embodiment of the subject matter disclosed herein.

FIGS. 7, 8 and 9 illustrate views of a brush block line replaceable unit for a tail rotor slip ring assembly according to an embodiment of the subject matter disclosed herein.

FIG. 10 illustrates a cutaway side view of a tail rotor slip ring assembly according to an embodiment of the subject matter disclosed herein.

FIG. 11 illustrates a block diagram of a tail rotor slip ring assembly according to an embodiment of the subject matter disclosed herein.

### DETAILED DESCRIPTION

In a helicopter, the main rotor and tail rotor slip rings provide circuit continuity between the stationary side and the rotational side of each rotor hub. The circuit continuity provides for transmission of electrical power to components mounted on each rotor hub (e.g., de-icing systems) and permits transmission of data signals from the rotor hubs to components mounted in the aircraft fuselage. The subject matter described herein is directed to slip ring assemblies and methods providing increased service life, improved reliability, greater resistance to contaminants, less wear debris, increased power capability, higher and cleaner data rates, higher durability, and/or reduced maintenance demands relative to conventional slip ring designs.

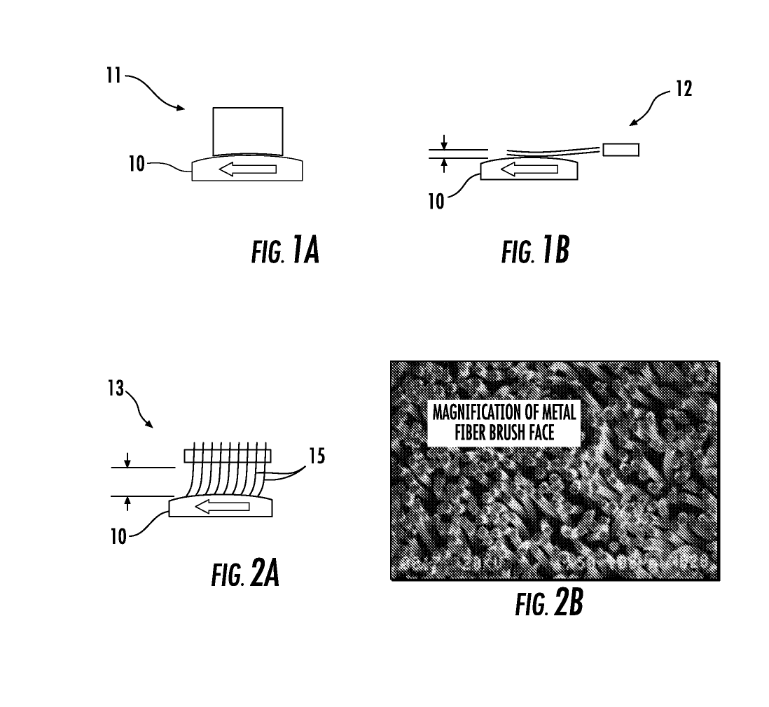

In this regard, in one aspect, the present subject matter provides an improved contact brush. In one conventional configuration shown in FIG. 1A, a monolithic carbon or metal-graphite brush 11 can be positioned in sliding contact with a sliding surface 10 (e.g., a slip ring drum). In this arrangement, constriction heating can develop due to the few number of contact points between monolithic brush 11 and sliding surface 10. In another conventional configuration shown in FIG. 1B, a metal brush 12 can be used for contact with sliding surface 10. In this configuration, however, there is very little available brush wear, which can result in a requirement for frequent replacement of metal brush 12.

In contrast to these conventional configurations, the present subject matter provides a metal fiber brush 13 constructed of hair-fine metal fibers 15. As shown in FIG. 2A, for example, each of metal fibers 15 is physically compliant, and each metal fiber brush 13 contains thousands of electrically independent contact points. As a result, most of metal fibers 15 contact sliding surface 10 individually, and thus at any given time there are many more points of contact than with a carbon brush, thereby providing high data integrity in high vibration environments. Further in this regard, because metal fiber brush 13 maintains better electrical contact with sliding surface 10, the potential for arcing and signal noise is significantly reduced. In addition, metal fibers 15 exhibit low brush wear and minimal debris generation. Accordingly, the design of metal fiber brush 13 creates very little wear on sliding surface 10. As a result, running on the tips of metal fibers 15 gives metal fiber brush 13 an increased maintenance interval for replacing the elements and provides a longer service life compared to other metal brushes (e.g., at least an order of magnitude in every side-by-side comparison in actual field testing). Additionally, by running metal fiber brush 13 on the tips of metal fibers 15, metal fibers 15 are better able to conform to sliding surface 10 and thus require less force as do carbon brushes (e.g., one-fifth as much or less). As a result, the amount of heating from sliding friction is reduced, and metal fiber brush 13 can thus have an increased service live compared to carbon or metal-graphite brushes (e.g., at least twice the service life). Also, by using a material for metal fiber brush 13 that is softer than that of sliding surface 10, the integrity of sliding surface 10 is better preserved.

In one embodiment, metal fiber brush 13 disclosed herein has a current density of 250 Amps/sq-in. In testing at 20A, 60 Hz, 115 VAC power, the voltage drop across the slip ring is about 26 millivolts or less. For comparison, the same test performed using silver graphite brushes yields a voltage drop of 400 millivolts. Regarding the electrical noise, when the slip rings are operating at rated speed of a helicopter rotor, and with 50 milliamperes applied, the variation in resistance of any circuit pair is configured to not exceed 50 milliohms peak-to-peak over a bandpass of about 1 Hz to about 100 kHz. In the embodiments discussed herein, the insulation resistance between adjacent current carrying parts or between any current carrying part and ground is about 100 megaohms at 500 V dc, and leakage current is less than 5 microamps. Further in this regard, the insulation between any two slip ring circuits and between any slip ring circuit and the assembly chassis is able to withstand a qualification dielectric test voltage of 1100 VRMS, 60 Hz, for 60±5 seconds, without failure or damage. The insulation is capable of withstanding 500 VRMS, 60 Hz, for 5 seconds and will have a maximum leakage current of 0.0001 ampere.

Alternatively or in addition to providing improved contact brushes, the present subject matter provides additional improvements to slip ring designs over conventional configurations. For instance, in another aspect, the present subject matter provides a configuration for a main rotor slip ring assembly, generally designated 100 in FIGS. 3a through 5. Main rotor slip ring assembly 100 provides circuit continuity between a stationary side and a rotational side of a main rotor hub to allow for electrical power and signals (e.g., power to de-ice systems) to pass to the components mounted on each rotor hub. Main rotor slip ring assembly 100 resides within an inner diameter of the rotor mast. An access port 106 is accessible through an access panel 108 providing an inspection window to enable visual inspection of the interface between the stationary elements and rotating elements of main rotor slip ring assembly 100. Accumulated brush debris is accessible and removable through this port without disassembly of the slip rings.

The lower end of main rotor slip ring assembly 100 is physically connected to a standpipe assembly, generally designated 102, while the upper end of main rotor slip ring assembly 100 is configured to physically attach to the mast mount. Specifically, for example, main rotor slip ring assembly 100 is configured to connect directly to a main rotor upper distributor via a mounting flange 103 and a first electrical connector 104 (e.g., a MIL-STD-5015 style electrical connector) that is configured to connect to a complementary connector located on the underside of the distributor. First electrical connector 104 is designed with a flange that contains a clocking pin, and it utilizes a 32-68P insert arrangement. The clocking pin fixes the position of the connector on the distributor, allowing the distributor and slip ring assembly to be blind mated.

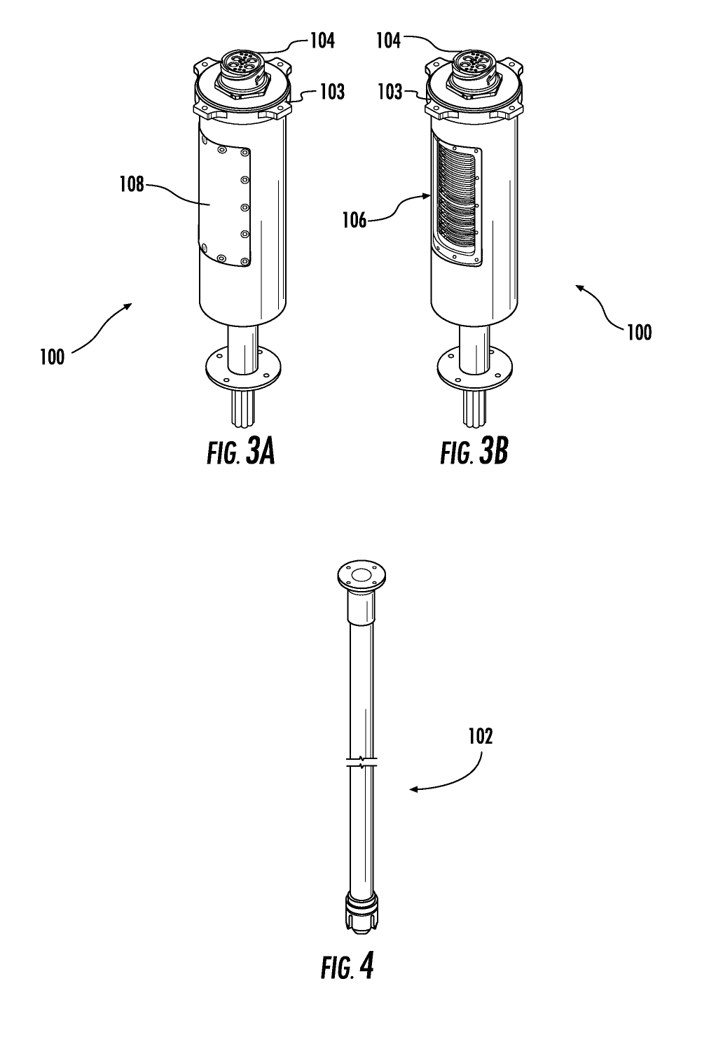

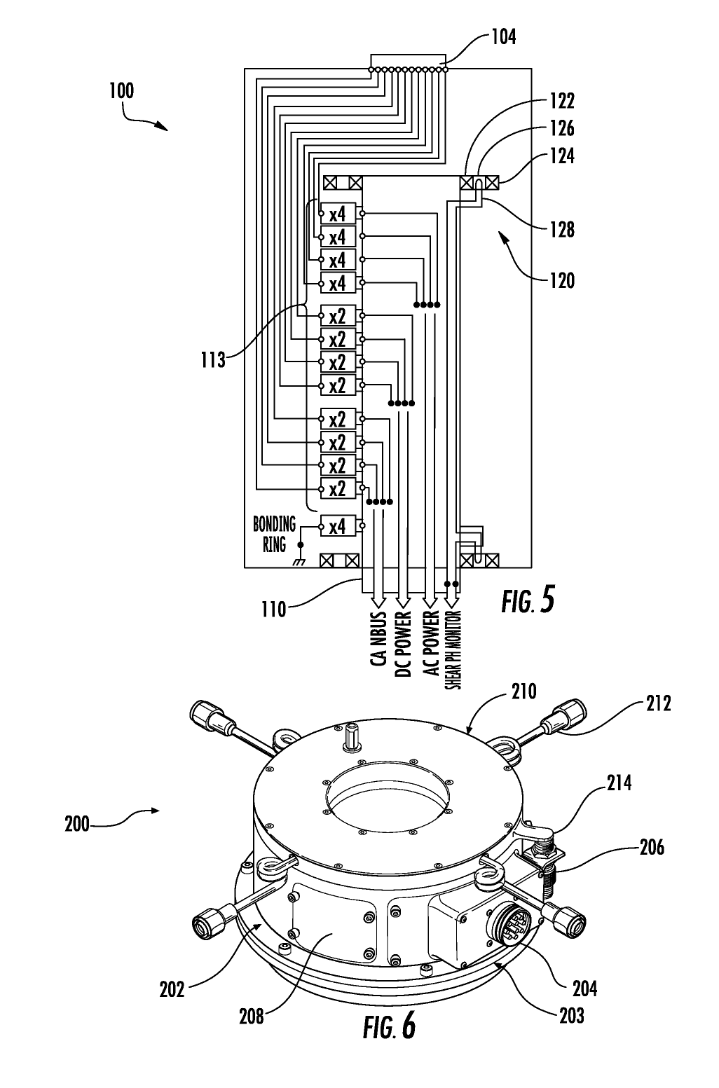

Main rotor standpipe assembly 102 is illustrated in detail in FIG. 4. Main rotor standpipe assembly 102 provides a mechanical linkage between an alignment pin that is located on the lower gearbox and the lower portion of main rotor slip ring assembly 100. Main rotor standpipe assembly 102 further provides a routing path for all wiring that exits from the lower portion of main rotor slip ring assembly 100. In the embodiments disclosed herein, the weight of main rotor slip ring assembly 100 and main motor standpipe assembly 102 is lightweight. In one embodiment, for example, the combined weight is about 19 pounds or less.

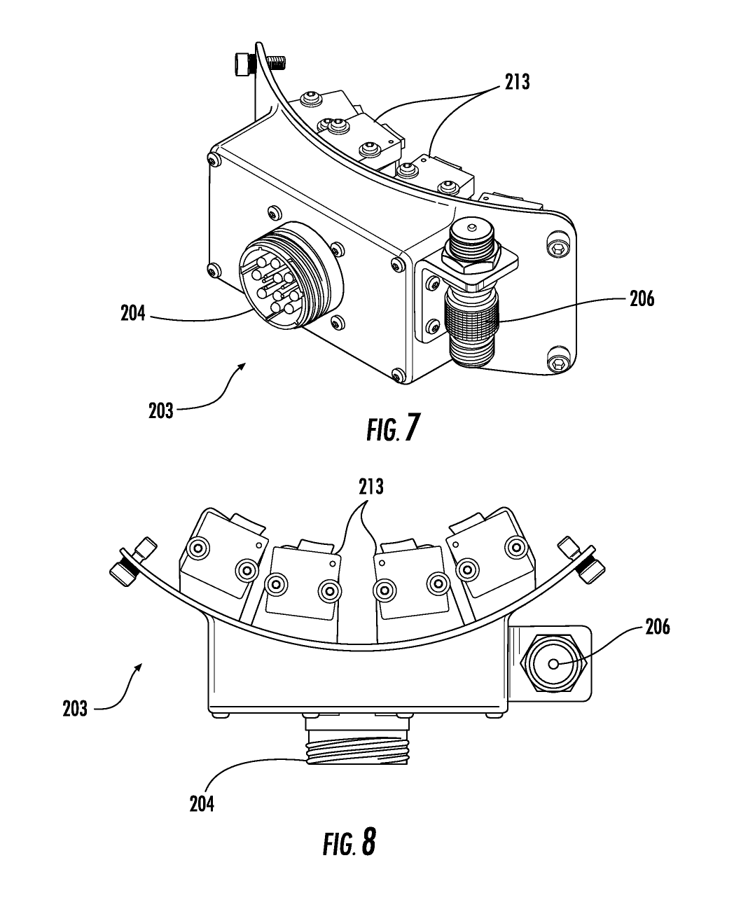

FIG. 5 illustrates a block diagram for one embodiment of main rotor slip ring assembly 100. As shown in FIG. 5, the wire bundle from the cabin is routed directly into a main rotor drum 110 of main rotor slip ring assembly 100. One or more first brush assembly 113 is connected directly to first electrical connector 104 (e.g., a MIL-DTL-5015 connector) on top of main rotor slip ring assembly 100. Although it is envisioned within the subject matter herein that each first brush assembly 113 is a metal fiber brush constructed of hair-fine metal fibers, as described above and shown in FIGS. 2A and 2B, any of a variety of contact brush configurations known in the art can be used for first brush assembly 113. Regardless of the particular configuration, first brush assembly 113 is configured to provide high data integrity in high vibration environments, reduced potential for arcing and signal noise, low brush wear, and minimal debris generation.

Regardless of the particular configuration of main rotor slip ring assembly 100, in the embodiments disclosed herein, the electrical power and signal information (e.g., ice protection system information) is transmitted across main rotor slip ring 100 via a Controller Area Network (CAN) bus in accordance with ISO-11898-2 with a data rate of at least up to 1 Mbps. Other data buses such as ARINC-429, ARINC-825 or MIL-STD-1553 can also be used. Impedance is less than about 240 ohms through the slip ring assembly. Unless very short cable lengths are used, about a 500 kpbs is recommended as the maximum transmission rate thru the slip ring channel. 500 kbps provides a more robust speed than 1 Mbps for aerospace applications and can tolerate many more fault conditions.

Regarding the particular electrical power and signals that are routed through main rotor slip ring assembly 100, Table 1 provides a pinout for one embodiment of first electrical connector 104 of main rotor slip ring assembly 100 (e.g., for a MRSRA MIL-DTL-5015 interface):

TABLE 1
Main Rotor Slip Ring Assembly Connector Interface

| MIL-DTL- | | | | Signal | Rated | Rated | |
|---|---|---|---|---|---|---|---|
| 5015 | | | Signal | Frequency | Current | Voltage | |
| 32-68 Pin | Ring # | Function | Type | (Hertz) | (Amps) | (Volts) | |
| A | 1 | Power A+ | Power | DC¹ | 100 | ±135 | DC |
| B | 2 | Power A− | Power | DC¹ | 100 | ±135 | DC |
| Q | 3 | Power B+ | Power | DC¹ | 100 | ±135 | DC |
| R | 4 | Power B− | Power | DC¹ | 100 | ±135 | DC |
| C | 5 | Low Power A+ | Power | DC¹ | <5 | 28 | DC |
| F | 6 | Low Power A− | Power | DC¹ | <5 | 28 | DC |
| G | 7 | Low Power B+ | Power | DC¹ | <5 | 28 | DC |
| H | 8 | Low Power B− | Power | DC¹ | <5 | 28 | DC |
| K | 9 | CAN Bus Ahigh | Data | 1 Mbps | <1 | 10 | V |
| L | 10 | CAN Bus Alow | Data | 1 Mbps | <1 | 10 | V |
| W | 11 | CAN Bus Bhigh | Data | 1 Mbps | <1 | 10 | V |
| P | 12 | CAN Bus BLow | Data | 1 Mbps | <1 | 10 | V |

To ensure high integrity of the electrical power and signals routed through main rotor slip ring assembly 100, the number of first brush assemblies 113 used to transmit power is selected to provide redundant transmission paths. As shown in Table 1, for example, quadruple redundant power brushes are provided.

Similarly, Table 2 illustrates one exemplary embodiment defining the cable bundle exiting from main rotor slip ring assembly 100 and traveling thru main rotor standpipe assembly 102 into the cabin:

TABLE 2
Main Rotor Slip Ring Assembly Cabin Cable Bundle Interface

| From | To | Ring | |
|---|---|---|---|
| Item | Item | Number | Wire Type |
| NVX-2178-1 | Cabin | 1 | M22759/2-6 |
| MRSRA | Power A | 2 | M22759/2-6 |
| | Cabin | 3 | M22759/2-6 |
| | Power B | 4 | M22759/2-6 |
| | Cabin 28 | 5 | MIL-W-22759/2-20 |
| | Power A | 6 | MIL-W-22759/2-20 |
| | Cabin 28 | 7 | MIL-W-22759/2-20 |
| | Power B | 8 | MIL-W-22759/2-20 |
| | Cabin | 9, 10 | M27500- |
| | CAN A | | 24ML2T08 |
| | Cabin | 11, 12 | M27500- |
| | CAN B | | 24ML2T08 |
| | Shear Pin | N/A | M27500- |
| | Monitor | | 24ML2T08 |

In one embodiment, the main de-ice power cables use 6-gauge 260C wires. For lower temperature rated cable, 4-gauge wires would be required, but the weight of the lower temperature rated cable bundle is significant. As a result, using 6-gauge wiring provides advantages where such use is permitted.

In one embodiment, main rotor slip ring assembly 100 has the electrical current and voltage ratings illustrated in Table 3 below.

TABLE 3
Main Rotor Slip Ring Assembly Current and Voltage Rating

| | | | Signal | Rated | Rated | |
|---|---|---|---|---|---|---|
| Ring | | Signal | Frequency | Current | Voltage | |
| Number | Function | Type | (Hertz) | (Amps) | (Volts) | |
| 1, 2 | Blade De-Ice | Power | DC¹ | 100 | ±135 | DC |
| | Power “A” | | | | | |
| 3, 4 | Blade De-Ice | Power | DC¹ | 100 | ±135 | DC |
| | Power “B” | | | | | |
| 5, 6 | Low Power | Power | DC¹ | <5 | 28 | DC |
| | “A” | | | | | |
| 7, 8 | Low Power | Power | DC¹ | <5 | 28 | DC |
| | “B” | | | | | |
| 9, 10 | CAN Bus “A” | Data | 1 Mbps | <1 | 10 | V |
| 11, 12 | CAN Bus “B” | Data | 1 Mbps | <1 | 10 | V |

¹Main rotor deice power is generated from a rectified 400 Hz input

Table 4 provides the main rotor slip ring current overload capability. The current overload capabilities are for the circuits contained in the main rotor slip rings.

TABLE 4
Main Rotor Slip Ring Current Overload

Percent Load
and Required Duration

| Slip Ring Size | 100% | 110% | 1000% |
|---|---|---|---|
| (100% Load | Load | Load | Load |
| 100 A | Continuous | Continuous | 150 msec |
| Less Than 10 A | Continuous | Continuous | 2 sec |

In addition to providing electrical power and signals to the components mounted on each rotor hub, main rotor slip ring assembly 100 is further configured to monitor the integrity of the bearing assembly that permits the movement of the rotating portions of main rotor slip ring assembly 100 relative to main rotor drum 110. For example, main rotor slip ring assembly 100 includes a main rotor bearing assembly 120 having a primary main rotor bearing 122 and a redundant secondary main rotor bearing 124 that is coupled to primary main rotor bearing 122 by a first shear pin 126. In this configuration, in the event of seizure between rotating and non-rotating parts of main rotor slip ring assembly 100 (bearing seizure, etc.), the torque developed in main rotor slip ring assembly 100 (i.e., between primary main rotor bearing 122 and main rotor drum 110) can cause first shear pin 126 to shear. Secondary main rotor bearing 124 is then engaged to provide rotatable support for the rotating elements of main rotor slip ring assembly 100 with respect to main rotor drum 110 and to allow free rotation between the rotating elements of main rotor slip ring assembly 100 and main rotor drum 110. For example, in one particular configuration, the design of first shear pin 126 is selected to shear at a torque between 50 and 100 times the normal torque of the primary bearing. In this way, seizure of the primary bearing will not cause seizure of the slip ring and thus will not damage aircraft wiring connected to the slip ring assembly, nor will it cause mechanical interference with other aircraft components.

Engagement of any of the slip ring back-up bearings is electrically indicated via a first shear pin monitoring circuit 128 embedded within main rotor drum 110 of main rotor slip ring assembly 100 (e.g., the leads are electrically connected in series in the non-rotating section of main rotor slip ring assembly 100) and sent down main rotor standpipe assembly 102. In one non-limiting configuration, first shear pin 126 provides a predetermined resistance of between about 0.25 ohms and 10 ohms when it is intact. If first shear pin monitoring circuit 128 exhibits a resistance that differs significantly from this predetermined normal resistance (e.g., greater than 10 ohms), failure of the shear pin and engagement of secondary main rotor bearing 124 is indicated. In the embodiments of the subject matter disclosed herein, first shear pin monitoring circuit 128 is monitored by the aircraft's Avionics System for indication of bearing seize as evidenced by shear pin shearing. In particular, the aircraft's Avionics System can determine that the first shear pin 126 has broken if a measured resistance differs significantly from the predetermined normal shear pin resistance.

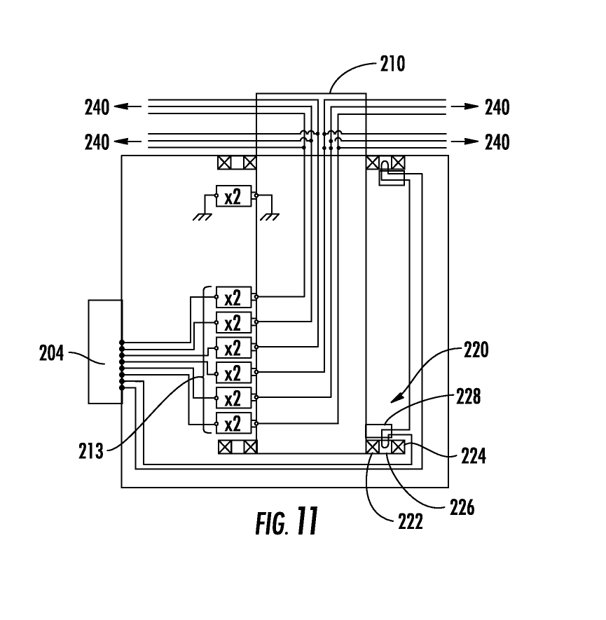

In still another aspect, the present subject matter provides a configuration for a tail rotor slip ring assembly, generally designated 200 in FIGS. 6 through 11. Similarly to main rotor slip ring assembly 100 with respect to a main rotor, tail rotor slip ring assembly 200 provides circuit continuity between a stationary side 202 and a rotational side 210 of a tail rotor hub to allow for electrical power and data signals (e.g., power to de-ice systems) to pass directly to the tail rotor blades. As shown in FIG. 10, for example, tail rotor slip ring assembly 200 is configured to be positioned about a tail rotor hub 230 at or near a position from which one or more tail rotor blades 240 extend from tail rotor hub 230.

One non-limiting configuration for tail rotor slip ring assembly 200 is illustrated in FIG. 6. As illustrated, tail rotor slip ring assembly 200 includes a second electrical connector 204 (e.g., a MIL-DTL-38999 electrical connector) on an aft quadrant of stationary side 202 to accommodate aircraft wiring. Tail rotor slip ring assembly 200 provides one or more un-terminated pigtail harnesses 212 on rotational side 210 of the assembly to accommodate rotor hub wire routing to the tail rotor blade disconnects. Tail rotor slip ring assembly 200 provides mounting provisions for a rotating pickup 214 and a stationary monopole sensor 206 (e.g., Honeywell 3030AN VRS) operable to measure the speed of rotation rotational side 210 with respect to stationary side 202.

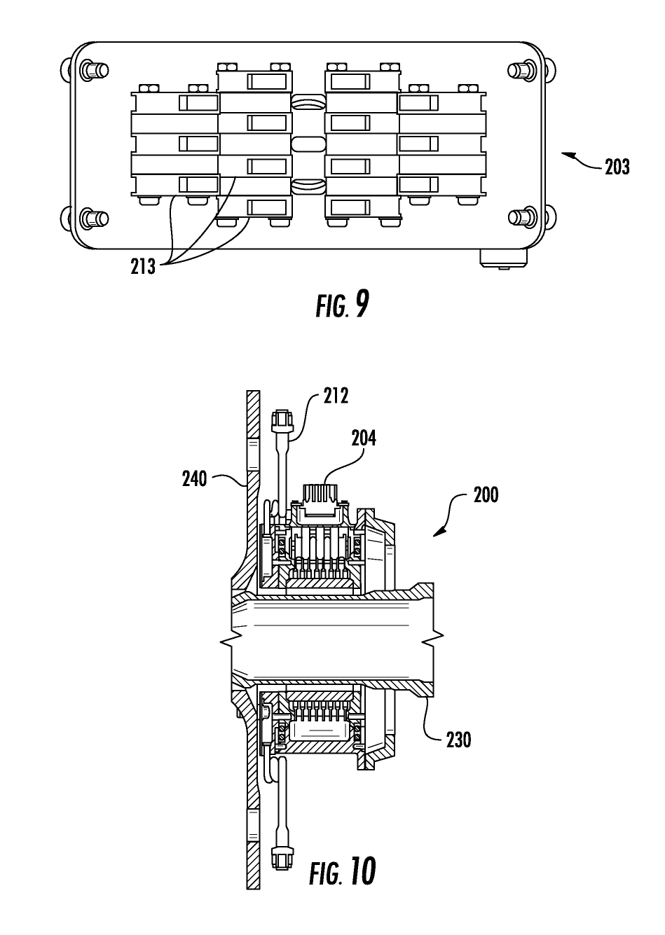

In one embodiment, tail rotor slip ring assembly 200 has a replaceable brush block assembly, generally designated 203, which is a separate line replaceable unit (LRU). In the configuration shown in FIGS. 7-9, for example, brush block assembly 203 is a single piece design, which also contains second electrical connector 204 (e.g. a MIL-DTL-38999 Shell Size G 21-99 connector). In this arrangement, brush block assembly 203 contains one or more second brush assembly 213. Although it is envisioned within the subject matter herein that each of the one or more second brush assembly 213 is a metal fiber brush constructed of hair-fine metal fibers as described above and shown in FIGS. 2A and 2B, any of a variety of contact brush configurations known in the art can be used for second brush assembly 213. Regardless of the particular configuration, each of the one or more second brush assembly 213 is configured to provide high data integrity in high vibration environments, reduced potential for arcing and signal noise, low brush wear, and minimal debris generation.

In addition to containing one or more second brush assembly 213, the embodiment of tail rotor slip ring assembly 200 further has blind mate attachment for a bearing shear pin monitoring circuit and the once-per-revolution stationary monopole sensor 206, which is routed to second electrical connector 204 to reduce cable bundles and connectors. As a result, each of the elements of tail rotor slip ring assembly 200 that may require periodic maintenance are provided together on brush block assembly 203. To conduct such maintenance, brush block assembly 203 is inspectable and replaceable, as necessary, at a defined periodic maintenance interval. For example, in the particular embodiment shown in FIG. 6, an inspection port 208 can be removable to enable visual inspection of the interface between the stationary elements and rotating elements of tail rotor slip ring assembly 200. Another example is that inspection port 208 is provided at approximately a 90-degree angle from brush block assembly 203. Accumulated brush debris is accessible and removable through this port without disassembly of the slip rings.

Alternatively or in addition, in the embodiments shown in FIG. 7 through 9, brush block assembly 203 is removable in its entirety from tail rotor slip ring assembly 200 for maintenance (e.g., repair and or replacement of one or more second brush assembly 213) or replacement. As a result, brush block assembly 203 is designed to be maintained and/or replaced at defined intervals, but the remainder of tail rotor slip ring assembly 200 is designed to last the life of the helicopter without replacement (although it may be replaced if desired). As discussed above, when using a metal fiber brush design for second brush assembly 213, even for those elements of brush block assembly 203 that are designed to be replaceable at specified maintenance intervals, very little wear is created on the slip ring drum. Therefore, second brush assembly 213 does not need to be replaced with great frequency. In addition, the metal fiber brush design also generates much less debris as compared to carbon based brush designs. As a result, inspection and maintenance of tail rotor slip ring assembly 200 to remove such debris can be conducted more infrequently compared to currently known conventional slip ring assemblies.

FIG. 11 illustrates a block diagram for one embodiment of tail rotor slip ring assembly 200. In the embodiment illustrated in FIG. 11, second electrical connector 204 is mounted on stationary side 202 of tail rotor slip ring assembly 200, which does not rotate, and one or more second brush assembly 213 is connected directly to second electrical connector 204. The one or more second brush assembly create an electrical contact with elements contained on rotational side 210, which carries cable bundles out to each blade (e.g., via pigtail harnesses 212). Regarding the particular electrical power and signals that are routed through tail rotor slip ring assembly 200, Table 5 illustrates one embodiment with a pinout for second electrical connector 204 (e.g., Mil-DTL-38999 Interface with a de-ice connector):

TABLE 5
Tail Rotor Slip Ring Assembly Connector Interface

| MIL- | | | | | | | |
|---|---|---|---|---|---|---|---|
| DTL- | | | | Signal | Rated | Rated | |
| 38999 | Ring | | Signal | Frequency | Current | Voltage | |
| Pin | # | Function | Type | (Hertz) | (Amps) | (Volts) | |
| A | 1 | Power AA | Power | 400 | 20 | 115 | AC |
| B | 2 | Power AB | Power | 400 | 20 | 115 | AC |
| C | 3 | Power AC | Power | 400 | 20 | 115 | AC |
| D | 4 | Power BA | Power | 400 | 20 | 115 | AC |
| E | 5 | Power BB | Power | 400 | 20 | 115 | AC |
| F | 6 | Power BC | Power | 400 | 20 | 115 | AC |
| M | N/A | Bearing | Signal | DC | <1 | <10 | V |
| | | Monitor | | | | | |
| K | N/A | Bearing | Signal | DC | <1 | <10 | V |
| | | Monitor | | | | | |

To ensure high integrity of the electrical power and signals routed through tail rotor slip ring assembly 200, the number of second brush assemblies 213 used to transmit power is selected to provide redundant transmission paths. As shown in Table 5, for example, quadruple redundant power brushes are provided.

In one embodiment, Table 6 provides tail rotor slip ring assembly 200 current and voltage rating:

TABLE 6
Tail Rotor Slip Ring Assembly Current and Voltage Rating

| | | | Signal | Rated | Rated |
|---|---|---|---|---|---|
| Ring | | Signal | Frequency | Current | Voltage |
| Number | Function | Type | (Hertz) | (Amps) | (Volts) |
| 1, 2, 3 | Blade De-Ice | Power | 400 | 20 | 115 AC |
| | Power “A” | | | | |
| 4, 5, 6 | Blade De-Ice | Power | 400 | 20 | 115 AC |
| | Power “B” | | | | |

Table 7 provides the tail rotor slip ring current overload capability. The current overload capabilities are for the circuits contained in the tail rotor slip rings:

TABLE 7
Tail Rotor Slip Ring Current Overload

Percent Load
and Required Duration

| Slip Ring Size | 100% | 110% | 1000% |
|---|---|---|---|
| (100% Load | Load | Load | Load |
| 20 A | Continuous | Continuous | 150 msec |
| Less Than 10 A | Continuous | Continuous | 2 sec |

In addition to providing electrical power and signals to the components mounted on each rotor hub, rotational side 210 is connected to a shear pin. The slip ring also has a bearing monitor circuit, which loops through the intermediate stage of each of two nested redundant bearings.

In this configuration, tail rotor slip ring assembly 200 includes a tail rotor bearing assembly 220 having a primary tail rotor bearing 222 and a redundant tail rotor secondary bearing 224 that is coupled to primary tail rotor bearing 222 by a second shear pin 226. In this configuration, in the event of seizure between rotating and non-rotating parts of tail rotor slip ring assembly 200 (bearing seizure, etc.), the torque developed in tail rotor slip ring assembly 200 (i.e., between primary tail rotor bearing 222 and rotational side 210) can cause second shear pin 226 to shear. Secondary tail rotor bearing 224 is then engaged to allow free rotation between the rotational side 210 and stationary side 202. For example, the design of second shear pin 226 is selected to shear at a torque between 50 and 100 times the normal torque of the primary bearing. In this way, seizure of the primary bearing will not cause seizure of the slip ring and thus will not damage aircraft wiring connected to the slip ring assembly, nor will it cause mechanical interference with other aircraft components.

Engagement of any of the slip ring back-up bearings is electrically indicated via a second shear pin monitoring circuit 228 embedded within stationary side 202 of tail rotor slip ring assembly 200 and connected to second electrical connector 204. In one particular configuration, a resistance measured in second shear pin monitoring circuit 228 is compared to a normal resistance across second shear pin 226 (e.g., between about 0.25 ohms and 10 ohms). A measured resistance that differs significantly from the expected normal resistance (e.g., greater than 10 ohms) indicates that second shear pin 226 has failed. In the embodiments of the subject matter disclosed herein, second shear pin monitoring circuit 228 is monitored by the aircraft's Integrated Avionics System for indication of bearing seize as evidenced by shear pin shearing.

Regardless of the particular configuration, the main and tail rotor slip ring assemblies are designed to operate continuously in the designed direction of rotation. For example, main rotor slip ring assembly 100 operates continuously at various combinations within the ranges of about 0 RPM to about 350 RPM, and main rotor slip ring assembly 100 operates at about 500 RPM for 30 minutes without degradation of performance. Tail rotor slip ring assembly 200 operates continuously at various combinations within the ranges of about 0 RPM to about 1500 RPM, and tail rotor slip ring assembly 200 operate at about 1750 RPM for 30 minutes without degradation of performance. The torque between the rotating and non-rotating parts of each slip ring assembly does not exceed about 0.6 foot-pounds at any RPM defined above for main rotor slip ring assembly 100 and tail rotor slip ring assembly 200. When either unit is unpowered, the respective slip ring can tolerate rotation in either clockwise or counterclockwise directions. The slip ring assemblies, minus the external wire cabling, are configured to be balanced such that the center of mass is within about 0.25 inches of the centerline of rotation.

In some embodiments, main rotor slip ring assembly 100 and standpipe assembly, and tail rotor slip ring assembly 200 and brush block assembly 203 are all line replaceable units (LRUs). As LRUs, each LRU incorporates electrical grounding features such that ground loops and common ground returns are avoided for signal and power circuits, effective shielding is provided for signal circuits, electromagnetic interference (EMI) is minimized, and personnel are protected from electrical hazards. Within the LRUs, the primary power returns, secondary power returns, and signal returns are not connected to the chassis. Rather, the LRUs are designed with more than 100 kilo ohms of isolation between the primary power return, the secondary power return, and the chassis case.

Main and tail rotor slip ring assemblies 100 and 200 are configured to require no on-aircraft mechanical adjustment or shimming of any LRU due to removal or replacement of any LRU. Instead, main and tail rotor slip ring assemblies 100 and 200 are configured to allow maintenance to be performed without inducing faults as a result of handling. As discussed above, main rotor slip ring assembly 100 and tail rotor slip ring assembly 200 have access panels (e.g., access port 106 and inspection port 208, respectively) for inspecting the brushes and drum of each slip ring assembly. If the operator or maintenance personnel choose to, brush block assembly 203 of tail rotor slip ring assembly 200 is replaceable. Once removed, visual inspection of the brushes, brush block assembly, and the slip ring can be performed. In addition, the failure of any one LRU, such as the slip rings and standpipe, will not cause a failure to any other LRU.

Each slip ring assembly has a minimum operating service life of about 10,000 hours. This service life anticipates periodic maintenance intervals. As discussed above, seizure between rotating and non-rotating parts of either main rotor slip ring assembly 100 and tail rotor slip ring assembly 200 slip ring assembly (e.g., bearing seizure, etc.) will not damage aircraft wiring connected to the respective slip ring assembly, nor will it cause mechanical interference with other aircraft components. In addition, wear of the metal fiber brushes and other slip ring components are designed to prevent degradation the electrical or mechanical performance of the slip ring assembly between maintenance cycles.

In this regard, main and tail rotor slip ring assemblies 100 and 200 are designed to minimize maintenance/support requirements including the need for special tools, support equipment, personnel skills, manpower, and elapsed maintenance time. In one embodiment, the preferred Maintenance Man Hour per Flight Hour (MMH/FH), including both scheduled and unscheduled maintenance actions for main rotor slip ring assembly 100 and standpipe assembly 102 is about a maximum of 0.00040. For the same conditions, the MMH/FH, including both scheduled and unscheduled maintenance actions for tail rotor slip ring assembly 200 is about a maximum of 0.00333.

In one embodiment, the Mean Time to Repair (MTTR) for the combination of main rotor slip ring assembly 100 and standpipe assembly 102 is about a maximum of 0.50 hours with an average maintenance crew size of 1.0 maintainer. For the same conditions, the MTTR for tail rotor slip ring assembly 200 is preferably about a maximum of 0.75 hours with an average maintenance crew size of 1.0 maintainer.

Similarly, the system is designed with a Mean Time Between Corrective Maintenance (MTBCM). In one embodiment, the inherent MTBCM of main rotor slip ring assembly 100 and standpipe assembly 102 is about a minimum of 10,000 flight hours. A failure is defined as any inherent deficiency that necessitates either immediate or deferred maintenance to correct. In some embodiments, scheduled maintenance for main rotor slip ring assembly 100 occurs in intervals of not less than 1,600 operating hours. Likewise, the inherent MTBCM of tail rotor slip ring assembly 200 is about a minimum of 3,000 flight hours, with a failure being defined as any inherent deficiency that necessitates either immediate or deferred maintenance to correct. In some embodiments, scheduled maintenance for tail rotor slip ring assembly 200 occurs in intervals of not less than 400 operating hours.

In the embodiments disclosed herein, main rotor slip ring assembly 100 (and standpipe assembly 102) and tail rotor slip ring assembly 200 (and brush block assembly 203) are capable of operating across a variety of extreme temperatures. In one embodiment, the slip rings maintain their performance in operating environments in ambient temperatures between about −49° F. (−45° C.) to about +39° F. (4° C.) for active heating conditions and about −49° F.(−45° C.) to about 158° F. (70° C.) for monitoring mode conditions. In another embodiment, the slip rings maintain their performance in non-operating environments following long periods of exposure to temperature extremes between about −65° F. (−54° C.) to about 185° F. (85° C.). The slip ring equipment will operate without functional degradation over the range of altitudes between about −2,000 feet to about +20,000 feet for active heating conditions and about −2,000 feet to about 25,000 feet for monitoring mode conditions. The slip ring is capable of operating without any component or system degradation in performance, and will sustain no physical damage during exposure to operations in ice and freezing rain conditions.

In one embodiment, main rotor slip ring assembly 100 (and standpipe assembly 102) and tail rotor slip ring assembly 200 (and brush block assembly 203) are capable of operating without degradation in any specified performance, and will sustain no physical damage during and after prolonged exposure to extremely high humidity levels, as encountered in tropical areas.

In one embodiment, the slip ring equipment is capable of operating without degradation in performance, and will sustain no physical damage, after exposure to the corrosive effects of a salt fog atmosphere. Similarly, the slip ring equipment is capable of operating without degradation in performance and will sustain no physical damage after exposure to blowing sand and dust particles that may by present within the aircraft.

In one embodiment, the slip ring equipment provides no nutrients in material, coating, or contaminant form to support fungal growth, and will operate as specified after exposure to the fungal growth that may be expected to be encountered in tropical areas.

Other embodiments of the current invention will be apparent to those skilled in the art from a consideration of this specification or practice of the invention disclosed herein. Thus, the foregoing specification is considered merely exemplary of the current invention with the true scope thereof being defined by the following claims.

What is claimed is:

1. A slip ring assembly, comprising:
a stationary element;
a rotating element rotatable with respect to the stationary element; and
one or more metal fiber brushes on one of the stationary element or the rotating element, each of the one or more metal fiber brushes comprising a plurality of metal fibers;
wherein the one or more metal fiber brushes are configured to transmit one or more of electrical power or data between the stationary element and the rotating element.

2. The improved slip ring assembly of claim 1, wherein the stationary element is connected to a chassis of a helicopter; and
wherein the rotating element is connected to a rotor hub of the helicopter.

3. The slip ring assembly of claim 1, wherein the one or more metal fiber brushes have a current density of about 250 Amps/sq-in or greater.

4. The slip ring assembly of claim 1, wherein a voltage drop across the one or more metal fiber brushes between the stationary element and the rotating element is about 26 millivolts or less.

5. The slip ring assembly of claim 1, comprising a bearing assembly coupled between the stationary element and the rotating element, the bearing assembly comprising:
a primary bearing;
a secondary bearing;
a shear pin coupling the secondary bearing to the primary bearing; and
an electrical monitoring circuit in communication with the shear pin.

6. The slip ring assembly of claim 6, wherein the second bearing provides rotatable support for the rotating element with respect to the stationary element if the shear pin is broken.

7. The slip ring assembly of claim 5, wherein the shear pin provides a predetermined resistance when the shear pin is intact.

8. The slip ring assembly of claim 7, wherein the predetermined resistance is between about 0.25 ohms and 10 ohms.

9. The slip ring assembly of claim 7, wherein the electrical monitoring circuit is configured to monitor a measured resistance of the shear pin; and
wherein the electrical monitoring circuit is configured to indicate that the shear pin has broken when the measured resistance of the shear pin differs from the predetermined resistance.

10. The slip ring assembly of claim 1, wherein the one or more metal fiber brushes comprise a replaceable brush block that is selectively connectible to the respective one of the stationary element or the rotating element.

11. The slip ring assembly of claim 10, comprising an electrical connector configured for electrically coupling the one or more metal fiber brushes to an electrical component connected to the slip ring assembly.

12. The slip ring assembly of claim 11, wherein the electrical component connected to the slip ring assembly comprises an ice protection system.

13. A slip ring assembly, comprising:
a stationary element;
a rotating element rotatable with respect to the stationary element;
a bearing assembly coupled between the stationary element and the rotating element, the bearing assembly comprising:
a primary bearing;
a secondary bearing;
a shear pin coupling the secondary bearing to the primary bearing; and
an electrical monitoring circuit in communication with the shear pin; and
one or more contact brushes on one of the stationary element or the rotating element, the one or more contact brushes being configured to transmit one or more of electrical power or data between the stationary element and the rotating element.

14. The slip ring assembly of claim 13, wherein the second bearing provides rotatable support for the rotating element with respect to the stationary element if the shear pin is broken.

15. The slip ring assembly of claim 13, wherein the shear pin provides a predetermined resistance when the shear pin is intact.

16. The slip ring assembly of claim 15, wherein the electrical monitoring circuit is configured to monitor a measured resistance of the shear pin; and
wherein the electrical monitoring circuit is configured to indicate that the shear pin has broken when the measured resistance of the shear pin differs from the predetermined resistance.

17. A method for transmitting one or more of electrical power or data between a stationary element and a rotating element, the method comprising:
coupling a bearing assembly between a stationary element and a rotating element rotatable with respect to the stationary element, the bearing assembly comprising:
a primary bearing;
a secondary bearing; and
a shear pin coupling the secondary bearing to the primary bearing;
measuring a resistance of the shear pin;
comparing the resistance of the shear pin to a predetermined resistance corresponding to an intact state of the shear pin; and
indicating that the shear pin has broken if the resistance of the shear pin differs from the predetermined resistance.

18. The method of claim 17, wherein measuring the resistance of the shear pin comprises measuring the resistance through an electrical monitoring circuit in communication with the shear pin.

19. The method of claim 17, wherein the predetermined resistance is between about 0.25 ohms and 10 ohms.

20. The method of claim 19, wherein indicating that the shear pin has broken comprises indicating that the resistance of the shear pin exceeds about 10 ohms.
